(19) United States
(12) Patent Application Publication
(10) Pub. No.: US 2024/0352268 A1
(43) Pub. Date: Oct. 24, 2024

(54) METAL OXIDE NANOPARTICLE DISPERSIBLE IN NON-POLAR SOLVENT, ELECTRON TRANSPORT LAYER-FORMING INK COMPOSITION FOR INKJET PRINTING INCLUDING THE SAME, PREPARATION METHOD THEREOF, AND LIGHT-EMITTING DEVICE AND DISPLAY INCLUDING THE SAME

(71) Applicants: SAMSUNG ELECTRONICS CO., LTD., Suwon-si (KR); HANSOL CHEMICAL CO., LTD., Seoul (KR)

(72) Inventors: Yeseul PARK, Suwon-si (KR); Dohyeong KIM, Seoul (KR); Somang KIM, Seoul (KR); Jaehong NOH, Seoul (KR); Sanghyun SOHN, Suwon-si (KR); Deahee LEE, Suwon-si (KR); Kyungnam KIM, Seoul (KR); Chunrae NAM, Seoul (KR); Gyucheol YOON, Seoul (KR); Sungmin HA, Seoul (KR)

(21) Appl. No.: 18/639,624

(22) Filed: Apr. 18, 2024

(30) Foreign Application Priority Data
Apr. 18, 2023 (KR) 10-2023-0050939

(51) Int. Cl. C09D 11/322; C07F 3/06; C09D 11/36; C09D 11/52; H10K 50/16; H10K 71/13

(52) U.S. Cl. CPC C09D 11/322; C07F 3/06; C09D 11/36; C09D 11/52; H10K 50/16; H10K 71/135

(57) ABSTRACT

A metal oxide nanoparticle for inkjet printing, where the metal oxide nanoparticle is surface modified and is dispersible in a non-polar solvent; an electron transport layer-forming ink composition for inkjet printing including the same; a preparation method for the metal oxide nanoparticle; and a light-emitting device and a display that are prepared with the metal oxide nanoparticle.

### CROSS-REFERENCE TO RELATED APPLICATION

This application is based on and claims priority under 35 U.S.C. § 119 to Korean Patent Application No. 10-2023-0050939, filed on Apr. 18, 2023, in the Korean Intellectual Property Office, the disclosure of which is herein incorporated by reference in its entirety.

### BACKGROUND

### 1. Field

The disclosure relates to a metal oxide nanoparticle and an electron transport layer-forming ink composition for inkjet printing including the same, a preparation method for the metal oxide nanoparticle, and a light-emitting device and a display that are prepared by including the metal oxide nanoparticle.

### 2. Description of the Related Art

Quantum dots (QDs), known as semiconductor nanocrystals, can produce various colors by generating light of different wavelengths depending on a particle size without a change in material type. Due to high color purity and high optical stability compared to existing luminants, QDs have attracted attention as a next-generation material for a light-emitting device.

In the display field, QDs are typically dispersed in a polymer matrix, and in the form of complexes, can be applied to various displays, electronic devices, in addition to TVs and LEDs.

Materials for color filters typically require high sensitivity, strong attachment force to a substrate, chemical resistance, heat resistance, or the like. In the past, the existing color filters applied to displays have been generally prepared by first forming a desired pattern through a photo-masked exposure process using a photosensitive resist composition, followed by a patterning process in which unexposed areas of the formed pattern were dissolved and removed by a development process. However, this manufacturing process was accompanied by problems including rising costs due to wasted materials.

Recently, in order to address upgrading of materials used in pixels and consequent cost increases, interest has been drawn to minimizing use of materials by using materials only in a desired area, rather than performing patterning with conventional spin-coating or slit-coating. The most representative technique is an inkjet method, such as a bubble jet method and a piezoelectric method. In an inkjet method, materials are typically used only for a desired pixel, and thus unnecessary waste of materials may be avoided.

Although, QD-containing solutions for inkjet printing have been widely studied, little research has been done on electron transport layer (ETL)-forming compositions for inkjet such as the ETL-forming compositions for inkjet printing disclosed in Korean Patent Application No. 10-2007-0078615. A need remains for materials suitable for inkjet printing.

### SUMMARY

Additional aspects will be set forth in part in the description which follows and, in part, will be apparent from the description, or may be learned by practice of the presented embodiments of the disclosure.

According to an embodiment, provided is a metal oxide nanoparticle for inkjet printing, wherein
the metal oxide nanoparticle is surface-modified, and
is dispersible in a non-polar solvent.

In an embodiment, the metal oxide nanoparticle is surface modified with an organic ligand having a hydrophobic moiety.

In an embodiment, the non-polar solvent is a mixture of at least two types of solvents.

In an embodiment, the non-polar solvent includes cyclohexylbenzene.

In an embodiment, the organic ligand is included in an amount of about 0.0001 moles to about 10 moles, based on 1 mole of a metal included in the metal oxide nanoparticle.

In an embodiment, the metal oxide nanoparticle is a zinc (Zn)-containing metal oxide nanoparticle.

In an embodiment of the disclosure, the metal oxide nanoparticle for inkjet printing, in which the Zn-containing metal oxide nanoparticle is alloyed with a metal capable of increasing a band gap of zinc oxide (ZnO).

In an embodiment, the Zn-containing metal oxide nanoparticle is zinc magnesium oxide (ZnMgO).

According to an embodiment, an electron transport layer-forming ink composition for inkjet printing includes a metal oxide nanoparticle that is surface-modified with an organic ligand, and
a non-polar solvent,
wherein the electron transport layer-forming ink composition is ejectable by inkjet printing.

In an embodiment, the non-polar solvent is a mixture of at least two types of solvents.

In an embodiment, the non-polar solvent includes cyclohexylbenzene.

In an embodiment, the non-polar solvent further includes at least one type of solvent selected from styrene, hexadecane, anisole, and cyclohexanone.

In an embodiment, the non-polar solvent has
a viscosity of about 1 cps to about 6 cps at 20° C.,
a vapor pressure about 0.001 mmHg to about 0.1 mmHg at 20° C., and
a surface tension about 30 dyn/cm to about 40 dyn/cm at 20° C.

In an embodiment, a volume ratio of the cyclohexylbenzene to other solvents is about 7:3 to about 20:1.

In an embodiment, the electron transport layer-forming ink composition has
a viscosity of about 1.0 cps to about 5.0 cps at 20° C.,
a vapor pressure of about 0.6 mmHg to about 45 mmHg at 20° C., and
a solids content of about 5 wt % to about 30 wt %.

In an embodiment, the organic ligand has a hydrophobic moiety.

In an embodiment, the metal oxide nanoparticle is a zinc (Zn)-containing metal oxide nanoparticle.

In an embodiment, the Zn-containing metal oxide nanoparticle is alloyed with a metal capable of increasing a band gap of zinc oxide (ZnO).

In an embodiment, the Zn-containing metal oxide nanoparticle is zinc magnesium oxide (ZnMgO).

In an embodiment, the organic ligand is included in an amount of about 0.0001 moles to about 10 moles, based on 1 mole of a metal included in the metal oxide nanoparticle.

According to an embodiment, a method of preparing an electron transport layer-forming ink composition for inkjet printing includes, preparing a metal oxide nanoparticle, modifying a surface of the metal oxide nanoparticle by adding an organic ligand to provide a surface-modified metal oxide nanoparticle, and mixing the surface-modified metal oxide nanoparticle with a non-polar solvent.

In an embodiment of the method, the organic ligand is included in an amount of about 0.0001 moles to about 10 moles based on 1 mole of a metal included in the metal oxide nanoparticle.

In an embodiment of the method, the non-polar solvent is prepared by mixing
cyclohexylbenzene, and
at least one type of solvent selected from styrene, hexadecane, anisole, and cyclohexanone.

In an embodiment of the method, a volume ratio of the cyclohexylbenzene to other solvents is about 7:3 to about 20:1.

According to an embodiment, a light-emitting device includes an electron transport layer prepared by using the electron transport layer-forming ink composition.

In an embodiment, the electron transport layer is formed through inkjet printing.

According to an embodiment, a display includes the light-emitting device.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is absorption spectra illustrating absorbance (arbitrary units) versus wavelength (nanometers) of metal oxide nanoparticles (ZnMgO) in accordance with Test Example 1;

FIG. 2 shows a TGA graph illustrating weight (percent) versus temperature (C) of ZnMgO in accordance with Test Example 2;

FIG. 3 shows an FT-IR spectrum illustrating normalized absorbance (arbitrary units) versus wavenumber (nanometers) of ZnMgO in accordance with Test Example 3;

FIG. 4 is a 1-drop image in accordance with Test Example 5;

FIG. 5A is a three-dimensional optical surface profile of the inkjet droplet shape in accordance with Example 1;

FIG. 5B is a graph illustrating thickness (nanometers) versus width (micrometer) of a cross-section of the inkjet droplet shape for Example 1 in accordance with Test Example 6;

FIG. 5C is a table of the ink droplet shape and coffee ring factor (CRF) results for Example 1 in accordance with Test Example 6;

FIG. 6A is a three-dimensional optical surface profile of the inkjet droplet shape in accordance with the Comparative Example;

FIG. 6B is a graph illustrating thickness (nanometers) versus width (micrometer) of a cross-section of the inkjet droplet shape for the Comparative Example in accordance with Test Example 6; and

FIG. 6C is a table of the ink droplet shape and CRF results for the Comparative Example in accordance with Test Example 6.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Throughout the disclosure, the expression “at least one of a, b or c” indicates only a, only b, only c, both a and b, both a and c, both b and c, all of a, b, and c, or variations thereof.

All terms (including technical and scientific terms) used in the present specification, unless otherwise defined, may be used with meanings that can be commonly understood by those skilled in the art to which the present invention pertains. In addition, terms defined in commonly used dictionaries are not to be interpreted ideally or excessively unless clearly specifically defined.

The term “organic group”, as used herein, refers to a linear or branched C1-C30 alkyl group, a linear or branched C2-C30 alkenyl group, a linear or branched C2-C30 alkynyl group, or the like. Here, the alkyl group, the alkenyl group, and the alkynyl group may each be substituted or unsubstituted.

The term “alkyl”, as used herein, refers to a monovalent substituent derived from a linear or branched C1-C30 saturated hydrocarbon. Examples thereof include methyl, ethyl, propyl, isobutyl, sec-butyl, pentyl, iso-butyl, hexyl, and the like, but are not limited thereto.

The term “alkenyl”, as used herein, refers to a monovalent substituent derived from a linear or branched C2-C30 unsaturated hydrocarbon with one or more carbon-carbon double bonds. Examples thereof include vinyl, allyl, isopropenyl, 2-butenyl, and the like, but are not limited thereto.

The term “alkynyl”, as used herein, refers to a monovalent substituent derived from a linear or branched C2-C30 unsaturated hydrocarbon with one or more carbon-carbon triple bonds. Examples thereof include ethynyl, n-propynyl, n-but-2-enyl, n-hex-3-enyl, and the like, but are not limited thereto.

The term “dispersible”, as used herein, refers to the capability of being substantially evenly distributed in a suspension or a colloid.

The solvent composition for quantum dot-containing emission layers to be used in a self-emissive display for inkjet printing, is under continued development due to limitations in the combination of existing materials with various solvent types. For example, when a polar solvent-based emission layer is used, technical problems can arise where an emission layer is etched when a polar solvent-based electron transport layer-forming ink composition of the same nature is used. Therefore, there is a need for metal oxide nanoparticles dispersible in non-polar solvents and an electron transport layer (ETL)-forming composition including the same.

Disclosed herein is a metal oxide nanoparticle that may be dispersible in a non-polar solvent to prevent etching of a polar solvent-based emission layer. The metal oxide nanoparticle may be included in an electron transport layer-forming ink composition for inkjet printing, in a light-emitting device, and a display. Provided are a metal oxide nanoparticle and an ETL-forming ink composition including the same, the metal oxide nanoparticle being dispersible in a non-polar solvent by modifying a hydrophilic surface of the metal oxide nanoparticle when using a polar solvent-based emission layer and being available for inkjet printing with viscosity control. Further disclosed is a preparation method for the metal oxide nanoparticle, and a light-emitting device and a display that include the metal oxide nanoparticle.

### Electron Transport Layer-Forming Ink Composition

An electron transport layer-forming ink composition according to an embodiment of the disclosure may be an ink composition that is ejectable by a general inkjet method to form an electron transport layer (ETL).

The ETL-forming ink composition according to an embodiment of the disclosure may include: a metal oxide nanoparticle that is surface-modified with an organic ligand; and a non-polar solvent.

Hereinafter, the composition of the ETL-forming ink composition will be described in detail as follows.

### Metal Oxide Nanoparticles

For use as metal oxide nanoparticles, materials used in ETLs in the art may be used without limitation. For example, common metal oxide nanoparticles used as dopant materials may be used, and non-limiting examples thereof include In₂S₃, Cu₂S, Ag₂S, ZnSe, ZnS, ZnO, ZnTe, ZnSe, TiO₂, SnO₂, ZnS, or a form in which at least one element is added to the aforementioned material.

In an embodiment of the disclosure, the metal oxide nanoparticle may be a zinc (Zn)-containing metal oxide nanoparticle, and more specifically, a metal (M) alloy with zinc oxide (ZnO) that may increase a band gap of ZnO [ZnMO (where M may be calcium (Ca) or magnesium (Mg)]. The metal M that may increase a band gap of the ZnO may be Ca or Mg. These metals are similar to the ionic radius of Zn, and thus may be incorporated into the ZnO lattice without causing stress. By reducing the size of ZnO, these metals may also increase the band gap of ZnO, for example, zinc magnesium oxide (ZnMgO).

As such, when such a metal alloy increases the band gap of the ZnO nanoparticles and is applied to form an ETL, an upshift of a conduction band minimum (CBM) level occurs, bringing the energy proximity between a CBM of a quantum dot-containing emission layer and the ETL, thereby lowering an energy barrier of electrons and consequently facilitating injection of electrons into a quantum dot region. Accordingly, a light-emitting device including an ETL with the alloyed ZnO nanoparticles may have excellent luminance and efficiency and high luminescence efficiency even at a lower driving voltage, compared to a device including an ETL with ZnO nanoparticles. In other words, when the ETL is applied, an electron injection barrier may be reduced, thereby reducing a driving voltage, improving efficiency, and furthermore, reducing power consumption of QLEDs. When the driving voltage of a device decreases, heat generation of a device also decreases, and thus a lifespan of a device may be expected to increase.

In an embodiment of the disclosure, an organic ligand having a hydrophobic moiety may be attached to a part or all of the surface of the metal oxide nanoparticle.

For use as the organic ligand, any organic ligand known in the art may be used without limitation, and some of the organic ligands may have functional groups with excellent affinity for the quantum dot surface. Examples of the organic ligand include functional groups such as a carboxylic acid, an acrylate, a pyridine, a thiol, a phosphine, a phosphine oxide, a primary amine, a secondary amine, a combination thereof, and the like.

The organic ligand may include a hydrophobic moiety where the hydrophobic moiety refers to parts of the organic ligand with non-polar functional groups such as hydrocarbon groups. The hydrophobic moiety may be a linear or branched C1-C30 alkyl group, a linear or branched C2-C30 alkenyl group, or a linear or branched C2-C30 alkynyl group, and more specifically, may be a linear or branched C5-C30 alkyl group, a linear or branched C5-C30 alkenyl group, or a linear or branched C5-C30 alkynyl group.

Non-limiting examples of the organic ligand available include oleic acid, myristic acid, lauric acid, palmitic acid, stearic acid, oleyl amine, n-octyl amine, hexadecyl amine, hexyl phosphonic acid, n-octyl phosphonic acid, tetradecyl phosphonic acid, octadecyl phosphonic acid, a combination thereof, and the like.

Such an organic ligand is attached to the surface of the metal oxide nanoparticle, surrounding the surface of the metal oxide nanoparticle with hydrophobic moieties. In this regard, the metal oxide nanoparticle may be mixed and dispersed in a non-polar solvent, and may play a role in ensuring film uniformity by reducing a coffee ring effect (CRE).

Here, the coffee ring effect refers to a phenomenon in which colloidal particles in a droplet move to the edge of the droplet by hydrodynamic effect during an evaporation process so that the density distribution of the particles becomes non-uniform. In other words, the smaller the particle size, the more it can move to the edge of the droplet, so that smaller particles are distributed closer to the edge of droplet, whereas large particles are distributed closer to the center of droplet.

An amount of the organic ligand is not particularly limited, and may be appropriately adjusted within the amount range known in the art. In consideration of dispersibility and film uniformity, the amount of the organic ligand may be, based on 1 mole of a metal, e.g., Zn, included in the metal oxide nanoparticle, about 0.001 moles to about 10 moles, and more specifically, about 0.001 moles to about 5 moles.

Meanwhile, in the disclosure, the metal oxide nanoparticle is mainly described as a material for forming an ETL. However, it is not limited to the aforementioned materials, and the application of organic materials or organic-inorganic composites available as a material for forming an ETL in the art also falls within the scope of the disclosure.

In the disclosure, the amount of the metal oxide nanoparticles is not particularly limited, and may be appropriately adjusted within a range known in the art. For example, the amount of the metal oxide nanoparticles may be, based on a total weight (e.g., 100 parts by weight) of the ETL-forming ink composition, about 5 parts by weight to about 30 parts by weight, more specifically, about 10 parts by weight to about 20 parts by weight.

### Non-Polar Solvent

Metal oxide nanoparticles in the art, such as ZnMgO, may use an alcohol-based solvent as a dispersion medium due to the nature of the material. When ethanol is used alone, the device characteristics may be exhibited, but inkjet ejection is not operative. In addition, when an emission layer of the same polar type as ethanol is used, the inevitable problem of etching of the emission layer cannot be avoided due to the use of the same solvent. Thus, finding a non-polar solvent that can disperse metal oxide nanoparticles in a non-polar solvent and also provide inkjet ejection capability has been a persistent challenge in the industry. A “non-polar solvent”, as used herein refers to a solvent with a dielectric constant of less than 20.

Meanwhile, the ejection conditions of inkjet equipment may be largely dependent on viscosity and vapor pressure. When the viscosity is too high or too low, a uniform film may not be obtained, and the vapor pressure may determine the degree of ejection. In the disclosure, the viscosity and vapor pressure suitable for inkjet ejection are considered, at least two types of mixed solvents that can satisfy these properties are selected, and the mixing ratio of these solvents is adjusted within a predetermined range, so as to prepare a solvent for the ETL-forming inkjet composition.

In an embodiment of the disclosure, the ETL-forming inkjet composition including at least two types of solvents may have a viscosity of about 1.0 centipoise (cps) to about 5.0 cps at 20° C., a vapor pressure of about 0.6 millimeters of mercury (mmHg) to about 45 mmHg at 20° C., and a solids content of about 5 weight percent (wt %) to about 30 wt %. In an embodiment, the viscosity may be about 1.2 cps to about 3.0 cps, the vapor pressure may be about 1.0 mmHg to about 30 mmHg, and the solids content may be about 5 wt % to about 25 wt %.

When the ETL-forming ink composition has the physical properties with the aforementioned solids content, viscosity, and vapor pressure, not only is inkjet ejection facilitated and improved, but also the uniformity of the ejected ink enables improved device characteristics to be exhibited.

When the ETL-forming ink composition according to the disclosure satisfies the aforementioned solids contents, viscosity, and vapor pressure characteristics, specific ingredients and/or amounts thereof of the at least two types of solvents included in the ETL-forming ink composition are not particularly limited.

In an embodiment of the disclosure, the non-polar solvent may include cyclohexylbenzene (CHB).

CHB with good dispersibility may be used as a main solvent in the disclosure, but regarding the inkjet ejection application, use of CHB alone may not be suitable in terms of viscosity. In this regard, other non-polar solvents with different viscosity than the viscosity of CHB may be combined in the composition, wherein the volume ratio of each solvent may be adjusted so that a final composition may simultaneously satisfy the aforementioned solids contents, viscosity, and vapor pressure characteristics.

For other non-polar solvents with a different viscosity than the viscosity of CHB, at least one type of solvent selected from styrene, hexadecane, anisole, and cyclohexanone may be used.

The composition may be prepared with CHB as a main solvent in the amount of 70 volume percent (vol %) or more based on the total volume of solvents. The volume ratio of CHB to other non-polar solvent(s) may be about 7:3 to about 20:1, for example, about 7:3 to about 9.5:0.5, and for example, about 7:3 to about 9:1. When the volume of non-polar solvent(s) other than CHB exceeds 30 vol % in the total solvents, the viscosity of the total solvents may increase, and the ejection performance of inkjet may decrease accordingly.

In addition, the characteristics of non-polar solvents mixed in the disclosure may include a viscosity of about 1 cps to about 6 cps at 20° C., a vapor pressure of about 0.001 mmHg to about 0.1 mmHg 20° C., and a surface tension of about 30 dynes per centimeter (dyn/cm) to about 40 dyn/cm at 20° C. When the characteristics of the mixed non-polar solvents are within the ranges above, these non-polar solvents may be suitable for use in an ink composition for inkjet printing.

In the disclosure, the total amount of the non-polar solvents in the ink composition is not particularly limited, and may be appropriately adjusted within a range known in the art. In an embodiment of the disclosure, the total amount of the non-polar solvents may be the remaining amount satisfying 100 parts by weight of the ETL-forming ink composition, and for example, may be about 70 parts by weight to about 95 parts by weight of 100 parts by weight of the composition.

### Other Additives

In addition to the aforementioned ingredients, the ETL-forming ink composition of the disclosure may use at least one additive known in the art without limitation to the extent that it does not impair the inkjet ejection performance.

Examples of usable additives include a light stabilizer, a heat stabilizer, a photo-initiation promoter, a heat-initiation promoter, a levelling agent, a toughening agent, a thickener, a colorant, a reactive diluent, a coupling agent, a dispersant, and the like. These additives may be used individually or in a combination of two or more types. Here, the amounts of these additives may be appropriately adjusted within a range known in the art, and are not particularly limited. In an embodiment of the disclosure, the amount of the at least one additive may be, based on the total weight of the ETL-forming ink composition, of about 0.01 parts by weight to about 5 parts by weight, for example, about 0.01 parts by weight to about 2 parts by weight.

### Preparation Method for ETL-Forming Ink Composition

The ETL-forming ink composition for inkjet printing according to the disclosure may be prepared by mixing and stirring the aforementioned surface-modified metal oxide nanoparticles, at least two types of non-polar solvents, and other additives that are mixed as necessary, according to methods known in the art.

In an embodiment of the disclosure, after preparing metal oxide nanoparticles, the surface of the metal oxide nanoparticles may be modified by adding an organic ligand, and the surface-modified metal oxide nanoparticles may be centrifuged and mixed with a non-polar solvent, so as to prepare the ETL-forming ink composition for inkjet printing.

Here, about 0.0001 moles to about 10 moles of the organic ligand may be added based on 1 mole of a main metal included in the metal oxide nanoparticles.

In addition, for use as the non-polar solvent, a mixture of two types of non-polar solvents may be used, and for example, CHB and other non-polar solvents may be mixed, wherein CHB and the other non-polar solvents may be mixed at a volume ratio of about 7:3 to about 20:1.

In an embodiment of the disclosure, the ETL-forming ink composition may be prepared as follows: (i) a basic substance is added to a reaction solution in which a Zn-containing compound and a compound including a metal capable of increasing a ZnO band gap are dissolved in a solvent, and the resulting solution is heated by stirring at a constant rate at a temperature of about 50° C. to about 80° C. for about 30 minutes to about 2 hours, (ii) an organic ligand with a mole percent of about 10% to about 70% relative to the moles of Zn ions contained in a Zn-containing compound is added to the resulting reaction solution, followed by heating by stirring at a constant rate at a temperature of about 80° C. to about 120° C. for about 10 minutes to about 1 hour, and then (iii) hexane and acetone are added to the solution, and the solution is centrifuged to provide surface-modified metal oxide nanoparticles. Next, (iv) the surface-modified metal oxide nanoparticles are mixed with a mixed solvent, which includes CHB and another non-polar solvent mixed at a volume ratio of 7:3, and dispersed therein, so as to prepare the ETL-forming ink composition.

In an embodiment of the disclosure, the Zn-containing compound and the metal-containing compound are not particularly limited, and materials known in the art may be used without limitation. In an embodiment of the disclosure, zinc acetate, zinc acetate dihydrate, zinc chloride, zinc nitrate, zinc sulfate, magnesium acetate tetrahydrate, or the like may be used.

In addition, the basic material is not particularly limited, and materials known in the art may be used without limitation. In an embodiment of the disclosure, for use as the basic material, at least one material selected from tetramethyl ammonium hydroxide (TMAH), potassium hydroxide (KOH), sodium hydroxide (NaOH), and amines may be used.

Non-limiting examples of suitable solvents to separate the surface-modified metal oxide nanoparticles based on solubility characteristics include hexane, benzene, xylene, toluene, octane, chloroform, chlorobenzene, tetrahydrofuran (THF), methylene chloride, 1,4-dioxane, diethyl ether, cyclohexane, dichlorobenzene, and the like, wherein the solvents may be used individually or in a combination of two or more types. In addition, non-limiting examples of the suitable non-solvents include acetone, ethanol, methanol, butanol, propanol, isopropyl alcohol, THF, dimethyl sulfoxide, dimethyl formamide, and the like, wherein the non-solvents may be used individually or in a combination of two or more types.

The mixing method in the preparation method is not particularly limited, and for example, mixers known in the art, such as a homodisper, a homomixer, a multi-purpose mixer, a planetary mixer, a kneader, a 3-roll mill, and the like, may be used.

The ETL-forming ink composition thus prepared may further include at least one of other additives such as a dispersant or the like.

The ETL-forming ink composition of the disclosure configured as described above may provide excellent workability and processability as the viscosity and vapor pressure characteristics are optimized. In particular, the ETL-forming ink composition of the disclosure may be useful for inkjet printing methods as both uniformity and stability are ensured in terms of inkjet ejection, a shape of the ejected ink, and a shape of the ink on a substrate.

### Light-Emitting Device and Display Apparatus

A light-emitting device according to an embodiment of the disclosure is distinguished from a light-emitting device in the art in that an ETL formed by the aforementioned ETL-forming composition is included.

A light-emitting device according to an embodiment of the disclosure may be a quantum dot light-emitting device, an organic light-emitting device, or the like, but is not limited thereto. The ETL-forming composition may be used in the manufacture of various types of light-emitting devices.

In general, a light-emitting device may include a first electrode, a second electrode facing the first electrode, an emission layer arranged between the first electrode and the second electrode, a hole transport layer arranged between the first electrode and the emission layer, and an ETL formed by the ETL-forming ink composition through inkjet printing. If necessary, the light-emitting device may further include at least one of a hole injection layer and an electron injection layer.

Here, the ETL may facilitate injection of electrons from the second electrode, and may serve to transfer electrons to the emission layer. The ETL may include Zn-containing metal oxide nanoparticles alloyed with a metal that can increase a ZnO band gap. In an embodiment of the disclosure, the ETL may be formed by inkjet printing the ETL-forming ink composition on the emission layer and then volatizing the solvent. The ETL of the disclosure may be provided in a single-layer structure so that it also serves as an electron injection layer, or may be formed in a stacked structure with a separate electron injection layer.

In addition, the disclosure provides a display apparatus including the ETL-forming ink composition. Here, the display apparatus may include a liquid crystal display (LCD) apparatus, an electroluminescent (EL) display apparatus, a plasma display panel (PDP) apparatus, a field emission display (FED) apparatus, an organic light-emitting device (OLED), or the like, but is not limited thereto.

Hereinafter, the disclosure will be described in more detail through the Examples. However, the Examples below are only for illustrating the disclosure, and the scope of the disclosure is not limited thereto.

### Example 1. Non-Polar Solvent-Based ETL-Forming Ink Composition for Inkjet

Zinc acetate (Zn(OAc)₂) and magnesium-acetate-tetrahydrate were dissolved in dimethyl-sulfoxide (DMSO), and then tetramethyl ammonium hydroxide (TMAH) was added thereto. The mixture was then heated to about 60° C. and the reaction was allowed to proceed for about 1 hour. Oleic acid was added in an amount of about 30 mole percent (mol %) of the number of moles of Zn(OAc)₂, and the resulting mixture was then heated to about 100° C. and the reaction was allowed to proceed for about 30 minutes. After about 30 minutes, the resulting solution was centrifuged and dispersed in a mixed solvent containing cyclohexylbenzene and styrene at a volume ratio of 7:3.

### Example 2

The same process as in Example 1 was followed, but the surface-modified solution was centrifuged twice and dispersed in cyclohexylbenzene and styrene at a volume ratio of 7:3.

### Example 3

The same process as in Example 1 was followed, but oleic acid was added in an amount of about 50 mol % of the number of moles of Zn(OAc)₂.

### Comparative Example. ETL-Forming Ink Composition in the Art (Polar Solvent-Based)

The solution obtained by completion of the reaction in the same manner as in Example 1 was used, but the reaction was terminated without the addition of an organic ligand (i.e., oleic acid). Hexane and acetone were added thereto to centrifuge particles, and the resulting particles were dispersed in a mixed solvent containing DMSO, ethanol, 2-methoxyethanol, and butanol in a volume ratio of 5:3:1:1.

### Test Example 1. Spectroscopic Evaluation

The absorption spectra were measured for the ETL-forming compositions prepared in Example 1 and Comparative Example.

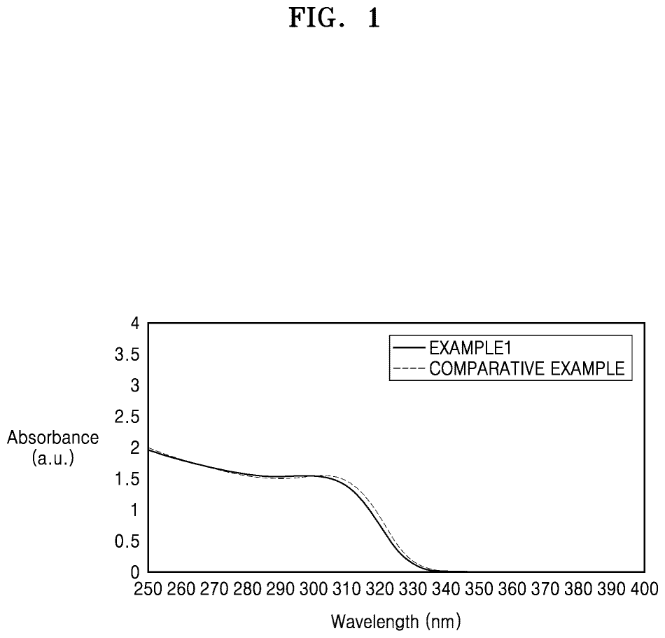

FIG. 1 provides both the UV-visible absorption spectrum of the ZnMgO nanoparticles synthesized in Example 1 (solid line) and the UV-visible absorption spectrum of the ZnMgO nanoparticles synthesized in Comparative Example (dashed line). As shown in FIG. 1, both have similar absorption spectra, and in particular, have a maximum absorption wavelength at about 305 nanometers (nm).

Accordingly, it was confirmed that, the ETL-forming composition with the metal oxide nanoparticles of Example 1 provided the same spectral characteristics as a typical polar solvent-based ETL-forming ink composition for inkjet printing.

### Test Example 2. TGA of ZnMgO Prepared in Examples 1 and 2 and Comparative Example

The thermogravimetric analysis (TGA) is a thermal analysis technique that measures changes in mass of a sample as the temperature changes over time. The temperature at which a rapid change in weight occurs may be interpreted as the decomposition temperature of organic materials, and the weight percent (wt %) of the organic materials may be calculated according to the amount of the total weight reduction.

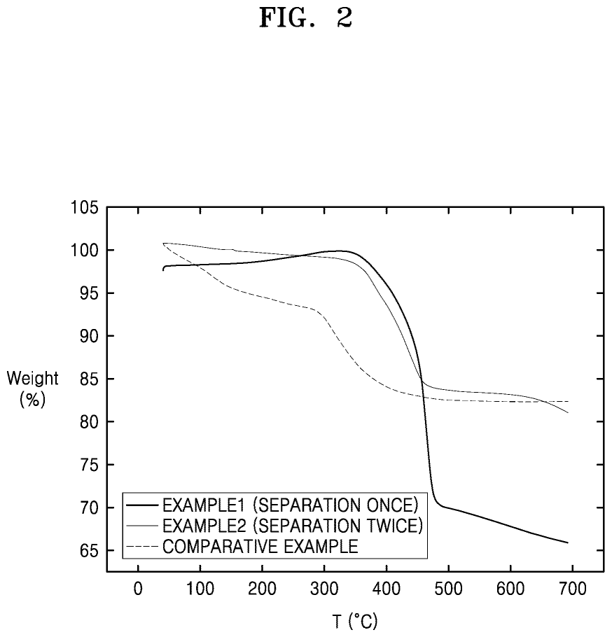

The TGA was performed for ZnMgO prepared in Examples 1 and 2 and Comparative Example, and the results are shown in Table 1 and FIG. 2.

TABLE 1

| | | | Comparative |
|---|---|---|---|
| Classification | Example 1 | Example 2 | Example |
| Weight | about 30% | about 15% | about 10% |
| (reduction %) | | | |
| Decomposition | 360° C. | 360° C. | 300° C. |
| temperature (° C.) | | | |

The organic materials included in the nanoparticles prepared in Comparative Example had a weight reduction of about 10%.

For Example 1, the organic materials had a weight reduction of about 30%, and for Example 2, the organic materials had a weight reduction of about 15%. In this regard, it was confirmed that with increased centrifugation time the more the organic ligand attached to the surface of ZnMgO separated from the nanoparticles.

In addition, the nanoparticles prepared in Comparative Example in which the organic ligand was not added had a decomposition temperature of about 300° C., whereas the nanoparticles prepared in Examples 1 and 2 had a decomposition temperature of about 360° C. Therefore, it was determined that the organic materials removed from the nanoparticles of the Comparative Example were the organic materials that were not removed during the centrifugation, and that the organic materials removed from the nanoparticles of Examples were the organic ligands attached to the surface of ZnMgO.

### Test Example 3. FT-IR Analysis of ZnMgO Prepared in Examples 1 and 3 and Comparative Example

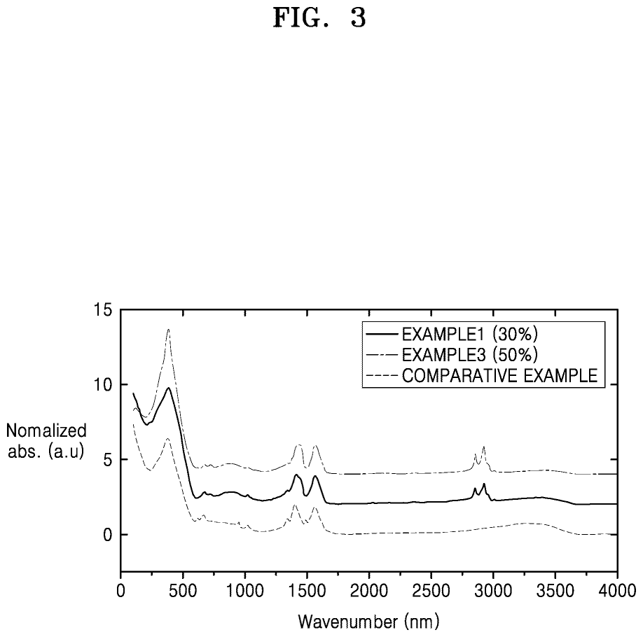

The Fourier-transform infrared spectroscopy (FT-IR) analysis was performed with ZnMgO prepared in Examples 1 and 3 and the Comparative Example, and the results are shown in FIG. 3.

Referring to FIG. 3, peaks of similar shapes appeared at 2,800 nm to 2,900 nm in Examples 1 and 3, but no peaks appeared in the same ranges for the Comparative Example. Therefore, it was confirmed that the organic ligands were well attached to the surface of ZnMgO prepared in the Examples.

### Test Example 4. Evaluation of Dispersibility of ZnMgO Prepared in Examples 1 and 3 and Comparative Example

ZnMgO prepared in Examples 1 and 3 and the Comparative Example was mixed and stirred with a non-polar solvent to confirm whether the nanoparticles were dispersed therein. For use as the non-polar solvent, a mixed solvent containing cyclohexylbenzene and styrene at a volume ratio of 7:3 was used. The results of the analysis are shown in Table 2.

TABLE 2

| | Example 1 | Example 3 | Comparative |
|---|---|---|---|
| Classification | (30%) | (50%) | Example |
| Dispersibility | Dispersible | Dispersible | Layer |
| | | | separation |

Accordingly, it was confirmed that the nanoparticles of Examples 1 and 3 were dispersible in the non-polar solvent regardless of the difference in the addition amount of the organic ligand, whereas the nanoparticles of Comparative Example showed no mixing at all with layer separation upon mixed with the non-polar solvent.

### Test Example 5. Evaluation of Inkjet Ejectability

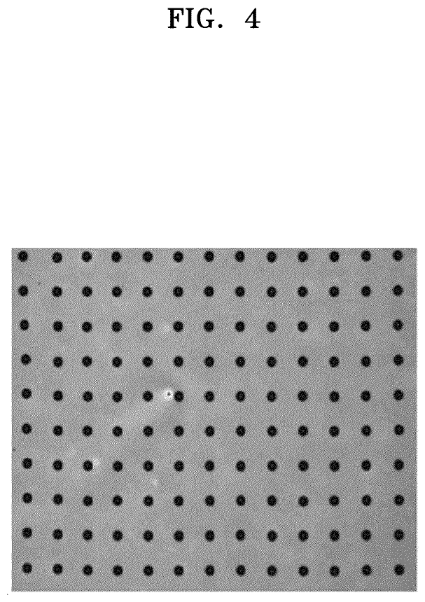

The ejectability associated with inkjet printing was evaluated for the ETL-forming ink composition of Example 1. In detail, each prepared ink composition was ejected with inkjet printing equipment (OMNIJET200), in the form of 1 drop, and the printed output is shown in FIG. 4.

Referring to FIG. 4, each dot was a circular shape, and no deformation was found such as invading the area of another dot or changing the spacing between dots.

### Test Example 6. Evaluation of Inkjet Shape (Based on CRF)

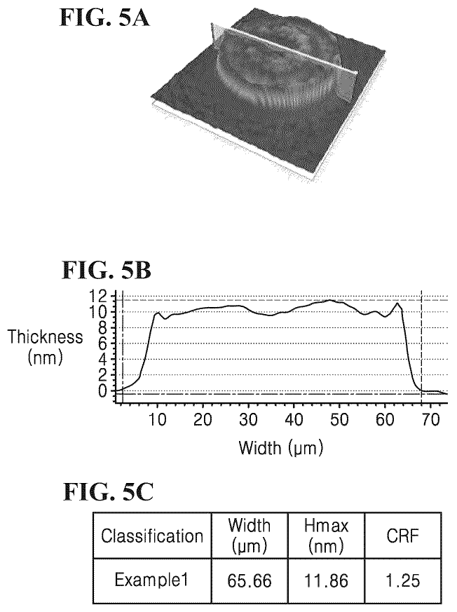

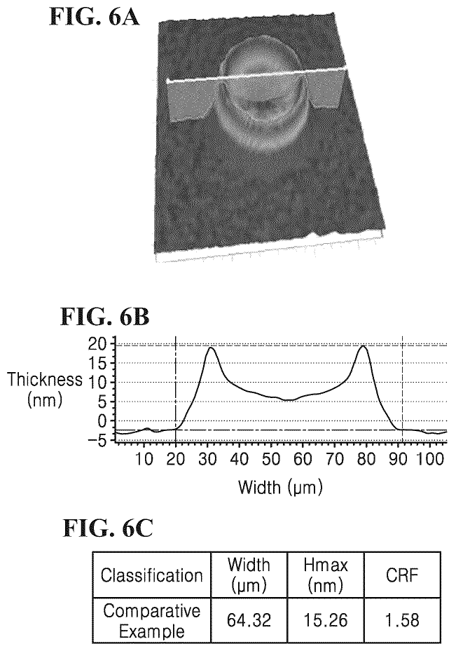

The ETL-forming ink compositions of Example 1 and Comparative Example were ejected with printing equipment (OMNIJET200), and the ink formed on a substrate was analyzed with a three-dimensional surface measuring instrument (NV9000, Zygo). The inkjet droplet shape, measurements, and degree of coffee ring effect are shown in FIGS. 5A-5C and 6A-6C. The degree of the coffee-ring effect was quantified using Equation 1.

Coffee-ring factor (CRF)=Hmax/Hmin Equation 1

In Equation 1, Hmax refers to the greatest thickness of a pattern, Hmin refers to the smallest thickness of a pattern, and the CRF value refers to the degree of the coffee-ring effect. That is, the CRF value of 1 indicates that the coffee-ring effect has been completely removed.

Referring to FIG. 5A, the surface profile of the inkjet droplet shape for Example 1 is shown. Measured height and width for a cross-section of the inkjet droplet shape for Example 1 is shown in FIG. 5B and the measurement results are shown in the table of FIG. 5C. The inkjet droplet shape had a Hmax of about 11.86 nm and a Hmin of about 9.49 nm (not shown). Accordingly, the CRF value was about 1.25. With a CRF value close to 1, the inkjet droplet shape had an even, three-dimensional shape overall, not just in one cross-section.

Meanwhile, referring to FIG. 6A, the surface profile of the inkjet shape for the Comparative Example is shown. Measured height and width for a cross-section of the inkjet droplet shape for the Comparative Example is shown in FIG. 6B and the measurement results are shown in the table of FIG. 6C. The inkjet droplet shape had a Hmax of about 15.26 nm and a Hmin of about 9.66 nm (not shown). Accordingly, the CRF value was about 1.58, which is much further from 1 than the results seen for Example 1. It was also confirmed that the coffee-ring effect was not only evident on one cross-section, but that the coffee-ring phenomenon occurred for the three-dimensional shape overall.

In addition, even though the same ink composition amount was ejected, the inkjet droplet of Example 1 had a Hmax of about 11.86 nm and the inkjet droplet of Comparative Example had a Hmax of about 15.26 nm. According to this comparison, it can be expected that the difference in height of the inkjet droplet shape could vary widely.

It is obvious to those skilled in the art that the disclosure is not limited to Examples above, and that various modifications or variations may be implemented without departing from the technical gist of the disclosure.

According to an embodiment of the disclosure, metal oxide nanoparticles that have been surface-modified may be mixed with two types of non-polar solvents, and in this regard, uniform ejection thereof by inkjet method may be facilitated.

In addition, when using a polar solvent-based emission layer, an electron transport layer-forming ink composition for inkjet printing capable of forming a uniform film on top of the emission layer may be provided, so that problems associated with etching of a polar solvent-based emission layer may be avoided.

Accordingly, the electron transport layer ink composition of the present invention can not only be usefully applied to the manufacture of light-emitting devices, such as self-emissive displays, through an inkjet printing process, but can also exhibit a more advantageous effect in commercialization and large-scale production through the application of a simple and inexpensive inkjet printing process.

The effects according to the disclosure are not limited to the contents exemplified above, and more diverse effects are included in the present specification.

What is claimed is:

1. A metal oxide nanoparticle for inkjet printing, wherein the metal oxide nanoparticle is surface modified with an organic ligand having a hydrophobic moiety,
wherein the organic ligand is included in an amount of about 0.0001 moles to about 5 moles, based on 1 mole of a metal included in the metal oxide nanoparticle, and
the metal oxide is dispersible in a non-polar solvent.

2. The metal oxide nanoparticle of claim 1, wherein the non-polar solvent is a mixture of at least two types of solvents.

3. The metal oxide nanoparticle of claim 2, wherein the non-polar solvent comprises cyclohexylbenzene.

4. The metal oxide nanoparticle of claim 1, wherein the metal oxide nanoparticle is a zinc-containing metal oxide nanoparticle.

5. The metal oxide nanoparticle of claim 4, wherein the zinc-containing metal oxide nanoparticle is alloyed with a metal capable of increasing a band gap of zinc oxide.

6. An electron transport layer-forming ink composition for inkjet printing, comprising:
a metal oxide nanoparticle that is surface-modified with an organic ligand having a hydrophobic moiety, wherein the organic ligand is included in an amount of about 0.0001 moles to about 5 moles, based on 1 mole of a metal included in the metal oxide nanoparticle; and
a non-polar solvent,
wherein the electron transport layer-forming ink composition is ejectable by inkjet printing.

7. The electron transport layer-forming ink composition of claim 6, wherein the non-polar solvent is a mixture of at least two types of solvents.

8. The electron transport layer-forming ink composition of claim 7, wherein the non-polar solvent comprises cyclohexylbenzene.

9. The electron transport layer-forming ink composition of claim 8, wherein the non-polar solvent further comprises at least one type of solvent selected from styrene, hexadecane, anisole, and cyclohexanone.

10. The electron transport layer-forming ink composition of claim 7, wherein the non-polar solvent has a viscosity of about 1 centipoise to about 6 centipoise at 20° C., a vapor pressure of about 0.001 millimeters of mercury to about 0.1 millimeters of mercury at 20° C., and a surface tension of about 30 dynes per centimeter to about 40 dynes per centimeter at 20° C.

11. The electron transport layer-forming ink composition of claim 8, wherein a volume ratio of the cyclohexylbenzene to other solvents is about 7:3 to about 20:1.

12. The electron transport layer-forming ink composition of claim 6, wherein the electron transport layer-forming ink composition has a viscosity of about 1.0 centipoise to about 5.0 centipoise at 20° C., a vapor pressure of about 0.6 millimeters of mercury to about 45 millimeters of mercury at 20° C., and a solids content of about 5 weight percent to about 30 weight percent.

13. The electron transport layer-forming ink composition of claim 6, wherein the metal oxide nanoparticle is a zinc-containing metal oxide nanoparticle.

14. The electron transport layer-forming ink composition of claim 13, wherein the zinc-containing metal oxide nanoparticle is alloyed with a metal capable of increasing a band gap of zinc oxide.

15. A method of forming an electron transport layer-forming ink composition for inkjet printing, the method comprising the steps of:
preparing a metal oxide nanoparticle;
modifying a surface of the metal oxide nanoparticle by adding an organic ligand having a hydrophobic moiety to provide a surface-modified metal oxide nanoparticle, wherein the organic ligand is included in an amount of about 0.0001 moles to about 5 moles, based on 1 mole of a metal included in the metal oxide nanoparticle; and
mixing the surface-modified metal oxide nanoparticle with a non-polar solvent.

16. The method of claim 15, wherein the non-polar solvent is prepared by mixing:
cyclohexylbenzene; and
at least one type of solvent selected from styrene, hexadecane, anisole, and cyclohexanone.

17. The method of claim 16, wherein a volume ratio of the cyclohexylbenzene to other solvents is about 7:3 to about 20:1.

18. A light-emitting device comprising an electron transport layer prepared with the electron transport layer-forming composition of claim 6.

19. The light-emitting device of claim 18, wherein the electron transport layer is formed through inkjet printing.

20. A display comprising the light-emitting device of claim 19.
